(19) United States
(12) Patent Application Publication
(10) Pub. No.: US 2026/0317885 A1
(43) Pub. Date: Oct. 15, 2026

(54) METHOD OF MANUFACTURING MASK FRAME ASSEMBLY AND DEVICE FOR MANUFACTURING MASK FRAME ASSEMBLY

(71) Applicant: SAMSUNG DISPLAY CO., LTD., YONGIN-SI (KR)

(72) Inventors: CHANGJUN KIM, Yongin-si (KR); SANGHYUK PARK, Yongin-si (KR); JANGHEE YU, Yongin-si (KR); JI-HUN JEONG, Yongin-si (KR)

(21) Appl. No.: 19/466,625

(22) Filed: Feb. 2, 2026

(30) Foreign Application Priority Data
Feb. 18, 2025 (KR) 10-2025-0020732

(51) Int. Cl. C23C 14/04

(52) U.S. Cl. CPC C23C 14/042

(57) ABSTRACT

A method of manufacturing a mask frame assembly includes preparing a first mask stick arranged on one surface of a mask frame having an opening and a second mask stick crossing the first mask stick, clamping the second mask stick at a first position, using a clamp, such that the first mask stick and the second mask stick cross at a compensation angle, fixing the first mask stick and the second mask stick, which form the compensation angle, to each other, moving the clamp to a second position, and fixing the second mask stick to one side of the mask frame.

### CROSS-REFERENCE TO RELATED APPLICATIONS

This application is based on and claims priority under 35 USC §119 to Korean Patent Application No. 10-2025-0020732, filed on Feb. 18, 2025, in the Korean Intellectual Property Office, the disclosure of which is incorporated by reference herein in its entirety.

### TECHNICAL FIELD

Embodiments of the present disclosure relate to a method of manufacturing a mask frame assembly and a device for manufacturing a mask frame assembly.

### DISCUSSION OF RELATED ART

Portable electronic devices have become increasingly common, with widespread use of mobile phones and, more recently, tablet PCs. These mobile devices often rely on display panels to deliver visual information such as images and videos.

As internal components used to drive display panels have become smaller, the display has come to occupy a greater proportion of the overall device. To accommodate this trend, display technologies have evolved to include structures that can flex or bend from a flat configuration to a curved state.

Display panels typically generate images by applying voltage to liquid crystal molecules, altering their arrangement. This change may affect optical properties such as, for example, birefringence, photopolarization, dichroism, or light scattering, which are then converted into visible image changes on the screen.

A variety of techniques exist for forming thin films on a substrate, including deposition methods that use a mask to pattern the deposited material. Two types of masks are commonly used: pattern masks, which include a plurality of pattern holes for forming a light-emitting layer, and open masks, which lack pattern holes and instead have openings for forming common layers.

To simplify manufacturing, open masks are often large enough to simultaneously process display panels of multiple sizes. These open masks are typically welded to a mask frame while a specified tensile force is applied.

### SUMMARY

Embodiments of the present disclosure provide a method of manufacturing a mask frame assembly and a device for manufacturing a mask frame assembly, capable of precisely manufacturing a mask frame assembly.

According to an embodiment of the present disclosure, there is provided a method of manufacturing a mask frame assembly including preparing a first mask stick arranged on one surface of a mask frame having an opening and a second mask stick crossing the first mask stick, clamping the second mask stick at a first position, using a clamp, such that the first mask stick and the second mask stick cross at a compensation angle, fixing the first mask stick and the second mask stick, which form the compensation angle, to each other, moving the clamp to a second position, and fixing the second mask stick to one side of the mask frame.

In some embodiments, the first position and the second position may be spaced apart in a direction in which the first mask stick extends.

In some embodiments, the compensation angle may be less than about 90 degrees.

In some embodiments, the moving of the clamp to the second position may be performed after the fixing of the first mask stick and the second mask stick to each other.

In some embodiments, the fixing of the second mask stick to one side of the mask frame may be performed after the moving of the clamp to the second position.

In some embodiments, the first position may be spaced apart from a second axis that is perpendicular to a first axis along which the first mask stick extends and passes through a crossing point of the first mask stick and the second mask stick.

In some embodiments, a vertical distance between the first position and the second axis may be greater than a vertical distance between the second position and the second axis.

In some embodiments, in the moving of the clamp to the second position, the clamp may rotate the second mask stick in a preset direction.

In some embodiments, in the moving of the clamp to the second position, the second mask stick may be rotated with respect to a crossing point of the first mask stick and the second mask stick.

In some embodiments, a length of the first mask stick may be greater than a length of the second mask stick.

According to an embodiment of the present disclosure, there is provided a device for manufacturing a mask frame assembly, which includes a mask frame having an opening, a first mask stick arranged on the mask frame, and a second mask stick arranged to cross the first mask stick, including a clamp configured to clamp an end of the second mask stick and move from a first position to a second position, a fixing device configured to fix the first mask stick and the second mask stick, and a controller configured to control a position of the clamp unit.

In some embodiments, the first position and the second position may be spaced apart in a direction in which the first mask stick extends.

In some embodiments, the controller may be configured to dispose the clamp at the first position such that the first mask stick and the second mask stick cross at a compensation angle less than about 90 degrees.

In some embodiments, the controller is configured to move the clamp to the second position after the fixing device fixes the first mask stick and the second mask stick to each other.

In some embodiments, the fixing device may be configured to fix the second mask stick to one side of the mask frame when the clamp is placed at the second position.

In some embodiments, the first position may be apart from a second axis that is perpendicular to a first axis along which the first mask stick extends and passes through a crossing point of the first mask stick and the second mask stick.

In some embodiments, a vertical distance between the first position and the second axis may be greater than a vertical distance between the second position and the second axis.

In some embodiments, the controller may be configured to move the clamp from the first position to the second position to rotate the second mask stick in a preset direction.

In some embodiments, the controller may be configured to move the clamp from the first position to the second position to rotate the second mask stick with respect to a crossing point of the first mask stick and the second mask stick.

In some embodiments, a length of the first mask stick may be greater than a length of the second mask stick.

### BRIEF DESCRIPTION OF THE DRAWINGS

The above and other features of the present disclosure will become more apparent by describing in detail embodiments thereof with reference to the accompanying drawings, in which:

FIG. 1 is a diagram schematically illustrating a device for manufacturing a mask frame assembly according to an embodiment of the present disclosure;

FIG. 2 is a top view of the device for manufacturing a mask frame assembly illustrated in FIG. 1;

FIG. 3 is a flowchart illustrating a method of manufacturing a mask frame assembly according to an embodiment of the present disclosure;

FIG. 4 is a diagram illustrating a process in which a clamp unit illustrated in FIG. 1 is placed at a first position so that a second mask stick forms a compensation angle with a first mask stick;

FIG. 5 is a diagram illustrating a process of cutting one side of the second mask stick by the device for manufacturing a mask frame assembly illustrated in FIG. 3;

FIG. 6 is a diagram illustrating a process in which the clamp unit moves to a second position in FIG. 4;

FIG. 7 is an enlarged view of portion A of FIG. 6;

FIG. 8 is a diagram illustrating a process in which the clamp unit of FIG. 5 applies tensile force to the second mask stick;

FIG. 9 is an enlarged view of portion B of FIG. 8;

FIG. 10 is a diagram illustrating a deposition device according to an embodiment of the present disclosure;

FIG. 11 is a schematic diagram illustrating an embodiment of a display device manufactured by a deposition device illustrated in FIG. 10; and

FIG. 12 is a cross-sectional view illustrating a subpixel of the display device of FIG. 11.

### DETAILED DESCRIPTION

Embodiments of the present disclosure will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

As used herein, the term "and/or" includes any and all combinations of one or more of the associated listed items. Expressions such as “at least one of,” when preceding a list of elements, modify the entire list of elements and do not modify the individual elements of the list.

Spatially relative terms, such as “beneath”, “below”, “lower”, “under”, “above”, “upper”, etc., may be used herein for ease of description to describe one element or feature’s relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below.

It will be understood that when a component is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

Herein, when two or more elements or values are described as being substantially the same as or about equal to each other, it is to be understood that the elements or values are identical to each other, the elements or values are equal to each other within a measurement error, or if measurably unequal, are close enough in value to be functionally equal to each other as would be understood by a person having ordinary skill in the art. For example, the term “about” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations as understood by one of the ordinary skill in the art, for example, within ± 30 %, 20 %, 10 % or 5 % of the stated value. Further, it is to be understood that while parameters may be described herein as having “about” a certain value, according to embodiments, the parameter may be exactly the certain value or approximately the certain value within a measurement error as would be understood by a person having ordinary skill in the art. Other uses of these terms and similar terms to describe the relationships between components should be interpreted in a like fashion.

Herein, it will be understood that the terms such as “including,” “comprising,” and “having” specify the presence of stated features or components, but do not preclude the presence or addition of one or more other features or components.

In the following embodiments, terms, such as connecting or combining, do not necessarily mean a direct and/or fixed connection or combination of two members, unless the context clearly indicates otherwise, and do not exclude that another member is interposed between the two members.

Embodiments of the present disclosure relate to assembling a mask frame using intersecting mask sticks that are joined at a compensation angle to accommodate deformation during fixation. For example, the method according to embodiments includes pre-setting an intersection angle between a first mask stick and a second mask stick prior to applying tensile force, such that any resulting distortion of the first mask stick during tensioning is offset. This approach may enable the second mask stick to ultimately align substantially parallel to the side of the mask frame to which it is fixed, despite the deformation that may naturally occur when tensile force is applied.

By controlling the initial crossing angle, referred to as the compensation angle, and coordinating the sequence of clamping, fixing, and pulling operations, the method according to embodiments allows for precise alignment of mask sticks during mask frame assembly. This may improve dimensional consistency across assembled units and reduce the risk of misalignment during deposition processes that rely on strict mask geometry. The described apparatus and method therefore may enable repeatable, high-accuracy assembly of mask frame components using relatively efficient mechanical operations.

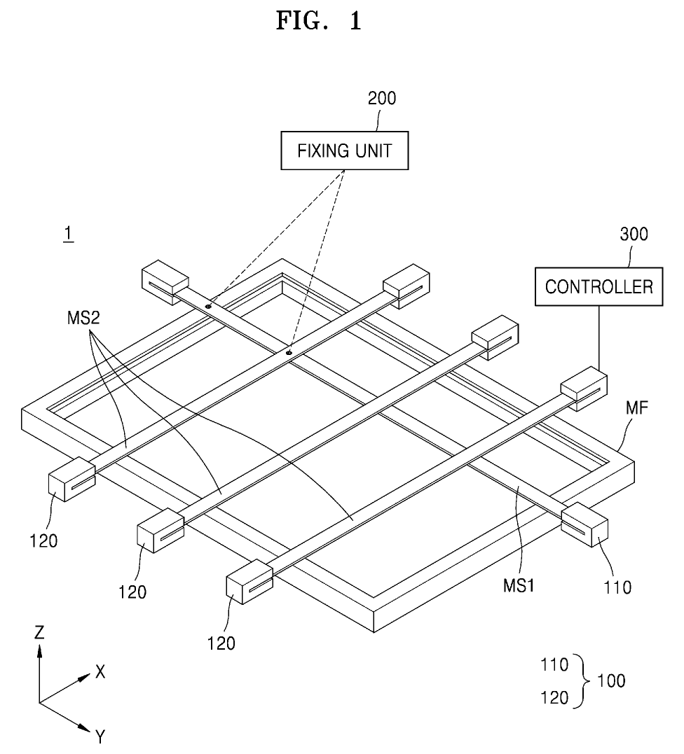

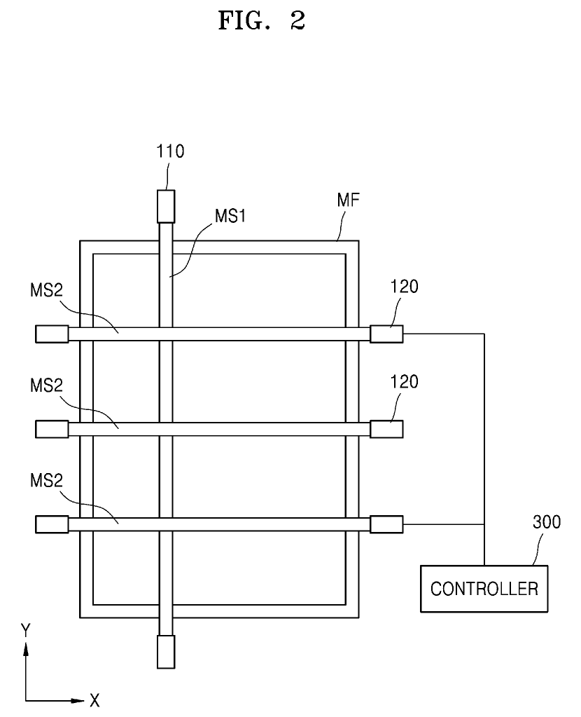

FIG. 1 is a diagram schematically illustrating a device 1 for manufacturing a mask frame assembly according to an embodiment of the present disclosure, and FIG. 2 is a top view of the device 1 for manufacturing a mask frame assembly illustrated in FIG. 1.

Herein, a mask frame assembly is for depositing a deposition material on a substrate and may include a first mask stick MS1 and a second mask stick MS2 partitioning and/or defining a deposition region and a mask frame MF that secures the first mask stick MS1 and the second mask stick MS2.

The mask frame MF may have a rectangular shape forming an opening through which a deposition material may pass, and for example, sides forming the mask frame MF may extend in a first direction and a second direction.

In an embodiment, the first mask stick MS1 may be relatively longer than the second mask stick MS2.

Herein, the ‘first direction’ may be interpreted as a direction in which one side of the mask frame MF extends, and for example, the first direction may be a direction in which the Y-axis (based on FIG. 1) extends.

The ‘second direction’ may be interpreted as a direction in which the other side of the mask frame MF extends, for example, the second direction may be a direction in which the X-axis (based on FIG. 1) extends, and the second direction may be a direction perpendicular to the first direction.

Herein, a ‘first axis AX1’ may be a longitudinal central axis of a first mask stick MS1, and, for example, the first axis AX1 may be an axis extending in the first direction.

A ‘second axis AX2’ may be a longitudinal central axis of a second mask stick MS2 when a clamp unit 100 that clamps the second mask stick MS2, for example, a second clamp 120, is placed at a second position P2.

A ‘third axis AX3’ may be a longitudinal central axis of the second mask stick MS2 when the clamp unit 100 that holds the second mask stick MS2, for example, the second clamp 120, is placed at a first position P1.

Referring to FIGS. 1 and 2, a device 1 for manufacturing a mask frame assembly according to an embodiment of the present disclosure may include the clamp unit 100, a fixing unit 200 (also referred to as a fixing device), and the controller 300 (also referred to as a controller circuit).

The clamp unit 100 clamps the first mask stick MS1 and the second mask stick MS2 and may include a first clamp 110 that clamps the first mask stick MS1 and the second clamp 120 that clamps the second mask stick MS2.

Herein, the clamp unit 100 may be interpreted as a term referring to either the first clamp 110 or the second clamp 120, or as a term referring collectively to the first clamp 110 and the second clamp 120. For example, the clamp unit 100 may also be referred to herein as a clamp.

The first clamp 110 may clamp the end of the first mask stick MS1. For example, the first clamp 110 may be provided in plurality, and the plurality of first clamps 110 may clamp opposite ends of the first mask stick MS1, respectively.

The first clamp 110 may move linearly in the first direction and/or the second direction. For example, the first clamp 110 may be powered from an external source and move linearly in the first direction and/or the second direction.

The plurality of first clamps 110 that clamp opposite ends of the first mask stick MS1 may move away from each other in the first direction, thereby applying tensile force in the first direction to the first mask stick MS1.

Accordingly, as the first clamp 110 moves in the first direction and applies tensile force to the first mask stick MS1, the fixing unit 200 may fix the first mask stick MS1 to which the tensile force is applied to the mask frame MF, which may reduce a phenomenon in which the first mask stick MS1 fixed to the mask frame MF sags.

The plurality of first clamps 110 clamping opposite ends of the first mask stick MS1 may move in the second direction, which may allow for precisely adjusting a position of the first mask stick MS1 in the second direction.

The controller 300 may adjust the position of the first clamp 110, and, for example, the controller 300 may simultaneously control the positions of the first clamps 110 clamping opposite ends of the first mask stick MS1.

The controller 300 may control the first clamps 110 clamping opposite ends of the first mask stick MS1 to move in the same direction.

For example, the controller 300 may control the second clamps 120 clamping opposite ends of the second mask stick MS2 to move in opposite directions based on the opening of the mask frame MF, and the controller 300 may control the first clamps 110 clamping opposite ends of the first mask stick MS1 to move in the same direction based on the opening of the mask frame MF.

Accordingly, the first clamp 110 may move the first mask stick MS1 in parallel in the first direction and/or the second direction, and the second clamp 120 may rotatably move the second mask stick MS2 so that the angle formed between the first mask stick MS1 and the second mask stick MS2 may change.

At a point after the first mask stick MS1 and the second mask stick MS2 are fixed, movement of the first clamp 110 in the second direction may be restricted.

For example, after the fixing unit 200 fixes the first mask stick MS1 and the second mask stick MS2 to each other, the controller 300 may restrict the first clamp 110 from moving in the second direction.

For example, after the fixing unit 200 fixes the first mask stick MS1 and the second mask stick MS2 to each other, the controller 300 may control the second clamp 120 to move from the first position P1 to the second position P2, and at the same time, the controller 300 may restrict the first clamp 110 from moving in the second direction.

The movement of the first clamp 110 may be restricted between a time when the first mask stick MS1 and the second mask stick MS2 are fixed and a time when tensile force is applied to the first mask stick MS1.

For example, between the time when the first mask stick MS1 and the second mask stick MS2 are fixed and the time when tensile force is applied to the first mask stick MS1, the second clamp 120 clamping the second mask stick MS2 may move from the first position P1 to the second position P2, and, at the same time, the movement of the first clamp 110 may be restricted.

For example, between the time when the fixing unit 200 fixes the first mask stick MS1 and the second mask stick MS2 and the time when the clamp unit 100 applies tensile force to the first mask stick MS1 and the second mask stick MS2, the controller 300 may control the second clamp 120 clamping the second mask stick MS2 to move from the first position P1 to the second position P2, and at the same time, the controller 300 may restrict the movement of the first clamp 110.

The clamp unit 100 may clamp the end of the second mask stick MS2 and may move from the first position P1 to the second position P2. For example, the second clamp 120 may clamp the end of the second mask stick MS2 and may move from the first position P1 to the second position P2 while clamping the second mask stick MS2.

Herein, the ‘first position P1’ is defined as a position of the second clamp 120 at which the first mask stick MS1 and the second mask stick MS2 form a compensation angle CA.

The ‘second position P2’ is defined as a position at which the second clamp 120 applies tensile force to the second mask stick MS2 and/or a position of the second clamp 120 at which one side of the second mask stick MS2 is positioned in a joining region of the mask frame MF.

Herein, the ‘joining region’ may be interpreted as a region on the mask frame MF which the second mask stick MS2 is in contact with and fixed to by the fixing unit 200.

The second clamp 120 may clamp the end of the second mask stick MS2. For example, the second clamp 120 may be provided in plurality, and the plurality of second clamps 120 may clamp opposite ends of the second mask stick MS2, respectively.

The second clamp 120 may move linearly in the first direction and/or the second direction. For example, the second clamp 120 may be powered from an external source and move linearly in the first direction and/or the second direction.

The plurality of second clamps 120 clamping opposite ends of the second mask stick MS2 may move away from each other in the second direction, which may apply tensile force in the second direction to the second mask stick MS2.

Accordingly, as the second clamp 120 moves in the second direction and applies tensile force to the second mask stick MS2, the fixing unit 200 may fix the second mask stick MS2 to which the tensile force is applied to the mask frame MF, which may reduce a phenomenon in which the second mask stick MS2 fixed to the mask frame MF sags.

The plurality of second clamps 120 clamping opposite ends of the second mask stick MS2 may move in the first direction, which may allow for precisely adjusting a position of the second mask stick MS2 in the first direction.

The controller 300 may adjust the position of the second clamp 120, and, for example, the controller 300 may simultaneously control the positions of the second clamps 120 clamping opposite ends of the second mask stick MS2.

For example, the controller 300 may control the second clamps 120 clamping opposite ends of the second mask stick MS2 to move in opposite directions based on the opening of the mask frame MF.

Accordingly, the second clamps 120 clamping opposite ends of the second mask stick MS2 may move in opposite directions to rotate the second mask stick MS2, which may adjust an angle formed by the first mask stick MS1 and the second mask stick MS2 so as to compensate in advance for an angle at which the first mask stick MS1 is twisted during the process of tensioning the second mask stick MS2.

Referring to FIG. 1, the fixing unit 200 according to an embodiment of the present disclosure may fix the first mask stick MS1 and the second mask stick MS2 to each other.

For example, the fixing unit 200 may fix the first mask stick MS1 to the second mask stick MS in a region in which the first mask stick MS1 crosses the second mask stick MS2 (hereinafter referred to as a ‘crossing point CP’).

The fixing unit 200 may fix the first mask stick MS1 to one side of the mask frame MF, and the fixing unit 200 may fix the second mask stick MS2 to the other side of the mask frame MF.

The fixing unit 200 may include various devices capable of fixing the first mask stick MS1 and the second mask stick MS2 to each other or fixing the first mask stick MS1 and the second mask stick MS2 to the mask frame MF. For example, the fixing unit 200 may include a laser welding device, a tungsten inert gas (TIG) welding device, a metal inert gas (MIG) welding device, a resistance welding device, an ultrasonic welding device, an electron beam welding device, a plasma arc welding device, and a spot welding device. The fixing unit 200 may also be referred to as a fixing device.

Referring to FIGS. 1 and 2, the controller 300 according to an embodiment of the present disclosure may control the position of the clamp unit 100.

For example, the controller 300 may adjust the angle formed by the first mask stick MS1 and the second mask stick MS2, apply tensile force to the first mask stick MS1 and/or the second mask stick MS2, or move the end of the second mask stick MS2 onto the joining region of the mask frame MF by controlling the position of the clamp unit 100.

For example, according to an embodiment, by fixing the first mask stick MS1 and the second mask stick MS2 to each other while the second clamp 120 is positioned at the first position P1, the two mask sticks may be welded together at a compensation angle CA that intentionally deviates from a right angle. This pre-applied angle may be formed in anticipation of the deformation of the first mask stick MS1 that may occur when tensile force is later applied to the second mask stick MS2, and may be selected such that the second mask stick MS2 ultimately aligns parallel to the mask frame MF after deformation.

According to an embodiment, the controller 300 may be configured to move the second clamp 120 from the first position P1 to the second position P2 only after the first and second mask sticks have been fixed together. This sequence may allow the pre-fixed compensation angle CA to be maintained while the second mask stick MS2 is repositioned in preparation for final fixation to the mask frame MF. By maintaining the compensation angle through this controlled repositioning operation, the apparatus may enable the second mask stick MS2 to ultimately align parallel to the mask frame MF, even in the presence of bending or twisting in the first mask stick MS1.

A method of controlling the position of the clamp unit 100 by the controller 300 is described in detail below when describing a method of manufacturing a mask frame assembly.

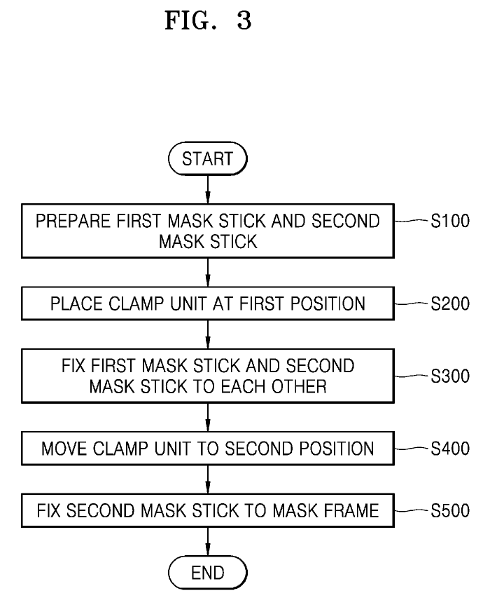

FIG. 3 is a flowchart illustrating a method of manufacturing a mask frame assembly according to an embodiment of the present disclosure.

Referring to FIG. 3, a method of manufacturing a mask frame assembly according to an embodiment of the present disclosure may include an operation (S100) of preparing the first mask stick MS1 arranged on one surface of the mask frame MF having the opening and the second mask stick MS2 crossing the first mask stick MS1, an operation (S200) of arranging the clamp unit 100 clamping the second mask stick MS2 in the first position P1 so that the first mask stick MS1 intersects the second mask stick MS2 to form the compensation angle CA, an operation (S300) of fixing the first mask stick MS1 and the second mask stick MS2 to each other to form the compensation angle CA, an operation (S400) of moving the clamp unit 100 to the second position P2, and an operation (S500) of fixing the second mask stick MS2 to one side of the mask frame MF.

When the second mask stick MS2 is fixed to the first mask stick MS1 at the crossing point CP and tensile force is then applied to the second mask stick MS2, the first mask stick MS1 to which the second mask stick MS2 is fixed may be twisted by a preset angle due to tensile force.

For example, due to tensile force applied to the second mask stick MS2, one side of the first mask stick MS1 may be deformed in the direction of the tensile force, and accordingly, the second mask stick MS2 fixed to one side of the first mask stick MS1 may be bent or deformed.

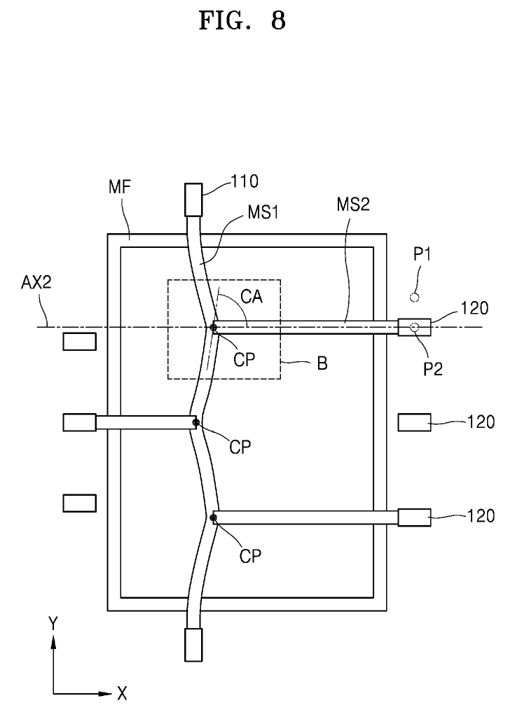

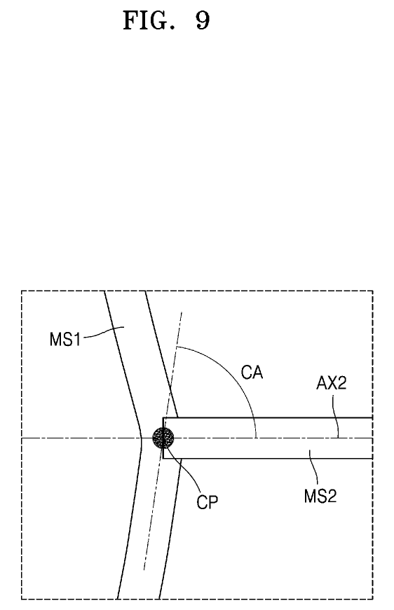

Due to this, distortion may occur on one side of the first mask stick MS1 to which the second mask stick MS2 is fixed with respect to the first axis AX1 due to at least one of the deformation of the first mask stick MS1 and the deformation of the second mask stick MS2 (see FIGS. 8 and 9).

Due to a distortion deformation occurring on one side of the first mask stick MS1, the second mask stick MS2 fixed to the one side of the first mask stick MS1 may be deflected to one side, which may result in a design error, such as the second mask stick MS2 being arranged non-parallel to one side of the mask frame MF.

According to the device 1 for manufacturing a mask frame assembly and a method of manufacturing a mask frame assembly according to an embodiment of the present disclosure, the second mask stick MS2 is fixed to the first mask stick MS1 so that the second mask stick MS2 and the first mask stick MS1 form the compensation angle CA in order to pre-compensate (correct) a deformation angle in the first mask stick MS1 and/or the second mask stick MS2. Thus, even if deformation occurs, the second mask stick MS2 may be manufactured so that it is entirely parallel or nearly parallel to one side of the mask. A detailed description thereof is provided below.

In the operation (S100) of preparing the first mask stick MS1 and the second mask stick MS2 crossing the first mask stick MS1, the controller 300 may control the operation of the clamp unit 100 to mount the first mask stick MS1 and the second mask stick MS2 on one surface of the mask frame MF.

According to an embodiment, in this method, the operation (S200) of placing the clamp unit at the first position P1 is performed prior to welding in order to introduce a compensation angle CA that anticipates deformation of the first mask stick MS1 caused by tensile force applied to the second mask stick MS2. This pre-positioning operation may allow the mask sticks to be joined with an intentional angular offset, which is selected based on expected mechanical behavior.

As a result, according to an embodiment, the overall manufacturing sequence from operation S100 through operation S500 may enable correction for post-weld bending effects without requiring iterative adjustment. By structuring the process to incorporate compensation geometry before tension is applied, the method may achieve parallel alignment of the second mask stick MS2 with the mask frame MF in a single, streamlined operation.

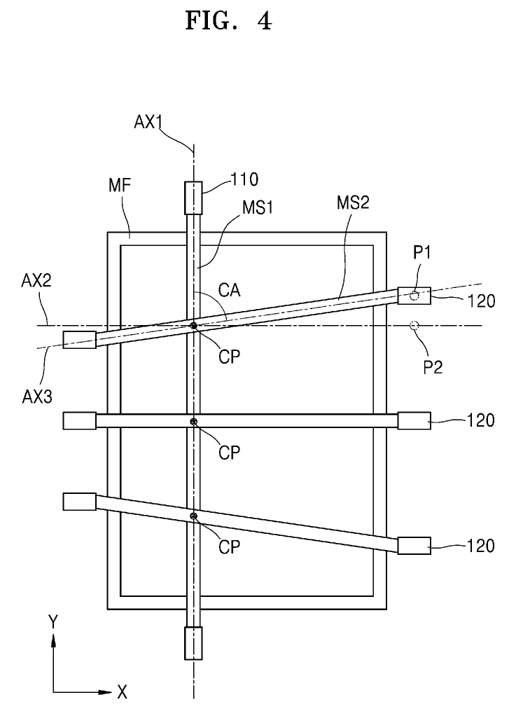

FIG. 4 is a diagram illustrating a process in which the clamp unit 100 illustrated in FIG. 1 is placed at the first position P1 so that the second mask stick MS2 forms the compensation angle CA with the first mask stick MS1.

The operation (S200) of placing the clamp unit 100 at the first position P1 may be performed before the operation (S300) of fixing the first mask stick MS1 and the second mask stick MS2 to each other.

Referring to FIGS. 3 and 4, in the operation (S200) of placing the clamp unit 100 at the first position P1, the controller 300 may place the second clamp 120 at the first position P1 such that the first mask stick MS1 and the second mask stick MS2 form the compensation angle CA.

For example, the controller 300 may move the position of the second clamp 120 that clamps the second mask stick MS2 to the first position P1 such that the first mask stick MS1 and the second mask stick MS2 form the compensation angle CA based on the crossing point CP.

Herein, the ‘compensation angle CA’ is an angle formed by the first mask stick MS1 and the second mask stick MS2 in order to compensate in advance for deformation occurring in the first mask stick MS1 and/or the second mask stick MS2 due to tensile force applied to the second mask stick MS2.

For example, the compensation angle CA may be about equal to or similar to an angle at which one side of the first mask stick MS1 to which the second mask stick MS2 is fixed is twisted or rotated when tensile force is applied to the second mask stick MS2 while the first mask stick MS1 and the second mask stick MS2 are fixed perpendicular to each other.

In an embodiment, the compensation angle CA may be less than about 90 degrees. For example, the compensation angle CA may be greater than or equal to about 85 degrees and less than or equal to about 90 degrees.

In the operation (S200) of placing the clamp unit 100 at the first position P1, the controller 300 may place the second clamp 120 at the first position P1 so that the second mask stick MS2 is placed along the third axis AX3.

Herein, the ‘third axis AX3’ is defined as an axis passing through the crossing point CP while forming the compensation angle CA with the first axis AX1.

The first position P1 may be spaced apart from the second position P2, and, for example, the first positions P1 may be spaced apart from the second position P2 in the direction in which the first mask stick MS1 extends.

The first position P1 may be spaced apart from the second axis AX2 that is perpendicular to the first axis AX1 along which the first mask stick MS1 extends and passes through the crossing point CP of the first mask stick MS1 and the second mask stick MS2.

A vertical distance between the first position P1 and the second axis AX2 may be relatively greater than a vertical distance between the second position P2 and the second axis AX2. For example, the second position P2 may be arranged on the second axis AX2, and the first position P1 may be spaced apart from the second axis AX2.

In the operation (S300) of fixing the first mask stick MS1 and the second mask stick MS2 to each other to form the compensation angle CA, the fixing unit 200 may fix the first mask stick MS1 and the second mask stick MS2 to each other at the crossing point CP.

The controller 300 may control the operation of the fixing unit 200 to fix the first mask stick MS1 and the second mask stick MS2 to each other to form the compensation angle CA. For example, the fixing unit 200 may weld the first mask stick MS1 and the second mask stick MS2 at the crossing point CP, thereby fixing the first mask stick MS1 and the second mask stick MS2 to form the compensation angle CA with each other.

The operation (S300) of fixing the first mask stick MS1 and the second mask stick MS2 to each other may be performed after the operation (S200) of placing the clamp unit 100 at the first position P1.

The operation (S300) of fixing the first mask stick MS1 and the second mask stick MS2 to each other may be performed before the operation (S400) of moving the clamp unit 100 to the second position P2.

In the operation (S300) of fixing the first mask stick MS1 and the second mask stick MS2 to each other, the second clamp 120 may be placed at the first position P1.

In the operation (S300) of fixing the first mask stick MS1 and the second mask stick MS2 to each other, the controller 300 may place the second clamp 120 at the first position P1 and control the operation of the second clamp 120.

In the operation (S300) of fixing the first mask stick MS1 and the second mask stick MS2 to each other, the movement of the first clamp 110 and the second clamp 120 may be restricted. For example, while the first mask stick MS1 and the second mask stick MS2 are fixed to each other, the controller 300 may restrict the first clamp 110 and the second clamp 120 from moving or rotating.

According to an embodiment, the use of the first position P1 when fixing the second mask stick MS2 to the first mask stick MS1 allows the compensation angle CA to be physically set at the moment of welding. If the second clamp 120 were placed instead at the second position P2, which corresponds to the final alignment target, the resulting angle at the crossing point CP would be perpendicular, and no compensation for deformation would be provided.

By fixing the mask sticks while the second clamp 120 is positioned at P1, and then later moving the clamp to P2 before applying tensile force, in an embodiment, the structure temporarily retains the intentionally offset geometry of the compensation angle CA. When tensile force is subsequently applied to the second mask stick MS2, deformation of the first mask stick MS1 causes the second mask stick MS2 to rotate into a state of parallel alignment with the mask frame MF, as intended.

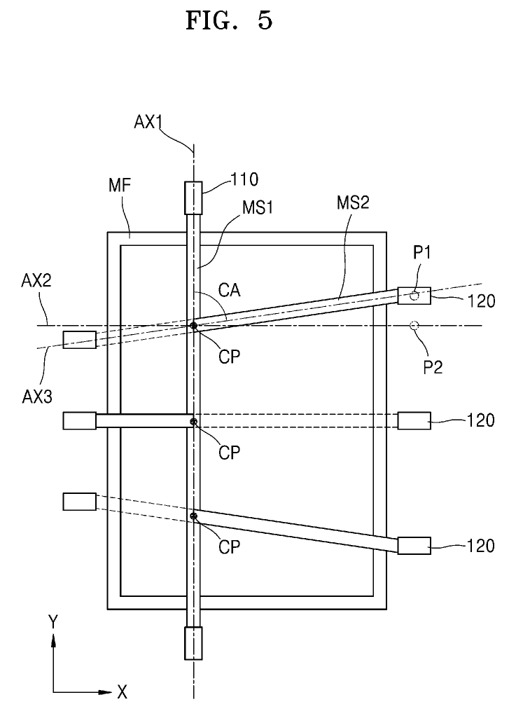

FIG. 5 is a diagram illustrating a process of the device 1 for manufacturing the mask frame assembly illustrated in FIG. 3 cutting one side of the second mask stick MS2.

Referring to FIG. 5, after the first mask stick MS1 and the second mask stick MS2 are fixed to each other, the controller 300 may cut one side of the second mask stick MS2. For example, after the first mask stick MS1 and the second mask stick MS2 are fixed to each other at the compensation angle CA, the controller 300 may cut one side of the second mask stick MS2 using a cutting unit.

Accordingly, by performing the process of fixing the second mask stick MS2 to the first mask stick MS1 and cutting the second mask stick MS2, the mask frame assembly may be partitioned from each other to form a plurality of deposition openings having preset widths.

According to an embodiment, cutting one side of the second mask stick MS2 after fixation at the compensation angle CA may also allow individual MS2 segments to respond more predictably to subsequent tensile force applied during final assembly. By separating MS2 into discrete sections between crossing points CP, each segment may better align with the corresponding joining region of the mask frame MF, promoting uniform deposition geometry across the entire mask frame assembly.

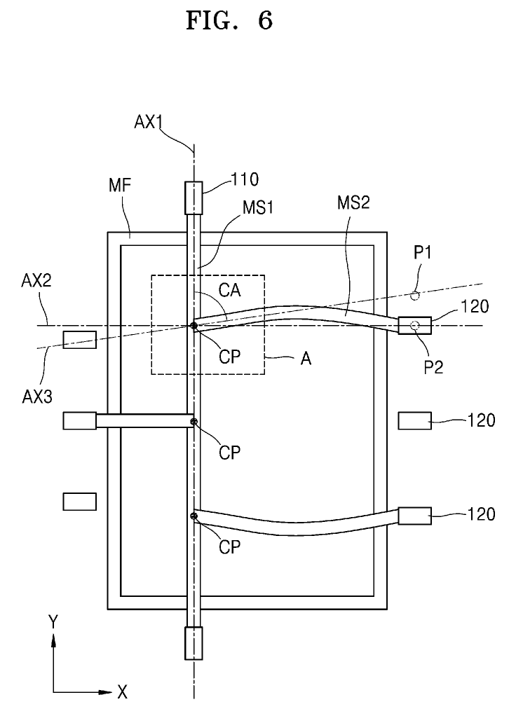

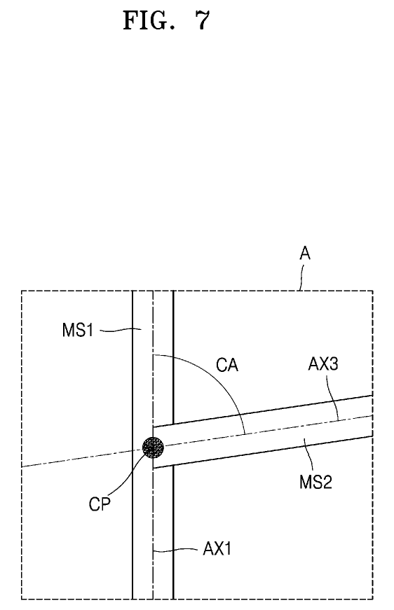

FIG. 6 is a diagram illustrating a process of the clamp unit 100 in FIG. 4 moving to the second position P2, and FIG. 7 is an enlarged view of portion A in FIG. 6.

Referring to FIGS. 3, 6 and 7, in the operation (S400) of moving the clamp unit 100 to the second position P2, the controller 300 may move the second clamp 120 that clamps the second mask stick MS2 to the second position P2.

In the operation (S400) of moving the clamp unit 100 to the second position P2, the controller 300 may move the second clamp 120 from the first position P1 to the second position P2 and may restrict the movement of the first clamp 110.

The operation (S400) of moving the clamp unit 100 to the second position P2 may be performed after the second mask stick MS2 is cut.

The operation (S400) of moving the clamp unit 100 to the second position P2 may be performed before the operation (S500) of fixing the second mask stick MS2 to one side of the mask frame MF.

The operation (S400) of moving the clamp unit 100 to the second position P2 may be performed before tensile force is applied to the second mask stick MS2. For example, the controller 300 may move the second clamp 120 from the first position P1 to the second position P2 before applying tensile force to the second mask stick MS2 by moving the second clamp 120 in the second direction.

In the operation (S400) of moving the clamp unit 100 to the second position P2, the second clamp 120 may rotate the second mask stick MS2 in a preset direction. For example, the second clamp 120 may rotate the second mask stick MS2 based on the crossing point CP of the first mask stick MS1 and the second mask stick MS2.

For example, the end of the second clamp 120 positioned on the mask frame MF may be rotated based on the crossing point CP of the first mask stick MS1 and the second mask stick MS2.

The second position P2 may be located on the second axis AX2.

An imaginary line passing through the crossing point CP of the first mask stick MS1 and the second mask stick MS2 and the second position P2 may be perpendicular to the first axis AX1.

In the operation (S400) of moving the clamp unit 100 to the second position P2, the second clamp 120 may move from the first position P1 to the second position P2 in the first direction, and for example, the controller 300 may control the operation of the second clamp 120 so that the second clamp 120 moves from the first position P1 to the second position P2 in the first direction.

In this case, even if the second clamp 120 clamps the end of the second mask stick MS2 and moves to the second position P2, because the second mask stick MS2 is fixed to the first mask stick MS1 while forming the compensation angle CA with the first mask stick MS1, the second mask stick MS2 still forms the compensation angle CA with the first mask stick MS1 at the crossing point CP.

In addition, because no tensile force is applied to the second mask stick MS2 in the operation (S400) of moving the clamp unit 100 to the second position P2, one side of the first mask stick MS1 to which the second mask stick MS2 is coupled may still extend along the first axis AX1 and the end of the second mask stick MS2 fixed to the one side of the first mask stick MS1 may extend along the third axis AX3.

In an embodiment, because the second mask stick MS2 is coupled to the one side of the first mask stick MS1 at the compensation angle CA, even if the second clamp 120 moves to the second position P2, which is a point on the second axis AX2, the end of the second mask stick MS2 coupled to the first mask stick MS1 may extend along the third axis AX3.

According to an embodiment, by executing the movement of the second clamp 120 from the first position P1 to the second position P2 prior to applying tensile force, the device 1 may isolate the mechanical repositioning of the second mask stick MS2 from any stress-induced deformation. This controlled movement may allow the compensation angle CA, which is predefined to counteract expected deformation, to be preserved at the crossing point CP throughout the clamping transition. As a result, the compensation angle CA may remain intact even as the clamp unit 100 transitions to a position aligned with the intended mounting direction.

According to an embodiment, this approach may facilitate improved alignment of the second mask stick MS2 relative to one side of the mask frame MF. Because the compensation angle CA is retained during the transition from P1 to P2 and before the application of tensile force, the second mask stick MS2 can ultimately be tensioned and fixed in a manner that results in its longitudinal axis being parallel, or nearly parallel, to the corresponding edge of the mask frame MF. This may reduce design errors caused by unintended deflection or angular misalignment, and may enable consistent formation of deposition openings having uniform widths.

FIG. 8 is a diagram illustrating a process in which the clamp unit 100 of FIG. 5 applies tensile force to the second mask stick MS2, and FIG. 9 is an enlarged view of portion B of FIG. 8.

Referring to FIGS. 3 and 8, in the operation (S500) of fixing the second mask stick MS2 to one side of the mask frame MF, the second clamp 120 may apply tensile force to the second mask stick MS2.

For example, the controller 300 may move the second clamp 120 located at the second position P2 in the second direction, through which the controller 300 may apply tensile force to the second mask stick MS2 clamped by the second clamp 120.

Referring to FIGS. 3 and 9, in this case, one side of the first mask stick MS1 located on the crossing point CP may be deformed toward the second clamp 120 due to tensile force applied to the second mask stick MS2.

For example, a deformation in which one side of the first mask stick MS1 is distorted or rotated by a preset angle may occur due to tensile force applied to the second mask stick MS2.

However, because the second mask stick MS2 is fixed to the first mask stick MS1 at the compensation angle CA, rather than at a right angle to correct/compensate for the distortion and/or rotational deformation angle of the first mask stick MS1 in advance, the second mask stick MS2 forming the compensation angle CA on the one side of the first mask stick MS1 in which deformation has occurred may be positioned parallel or nearly parallel to one side of the mask frame MF.

In the operation (S500) of fixing the second mask stick MS2 to one side of the mask frame MF, the fixing unit 200 may fix one side of the second mask stick MS2 to the mask frame MF, while the second clamp 120 applies tensile force to the second mask stick MS2.

The method of manufacturing a mask frame assembly and the device 1 for manufacturing a mask frame assembly according to embodiments of the present disclosure may have the effect of precisely manufacturing a mask frame assembly by combining the first mask stick MS1 and the second mask stick MS2 using the preset or calculated compensation angle CA.

According to an embodiment, the compensation angle CA may be determined based on a known or experimentally derived correlation between the tensile force applied to the second mask stick MS2 and the resulting deformation angle of the first mask stick MS1 at the crossing point CP. For example, the compensation angle CA may be calculated based on one or more of the tensile modulus of the mask stick materials, the dimensions of the mask sticks, the clamping geometry, and the expected magnitude and direction of the applied tensile force. By setting the compensation angle CA accordingly, the final position of the second mask stick MS2 can be predicted and controlled with high precision.

By integrating the compensation angle CA into the initial fixation of the second mask stick MS2 to the first mask stick MS1, the device 1 and method according to embodiments may eliminate the need for iterative feedback or post-assembly realignment steps to correct for deformation-induced misalignment. This may facilitate repeatable, high-throughput manufacturing of mask frame assemblies with reduced variation in pattern accuracy, which may improve production yield and device quality in downstream processes.

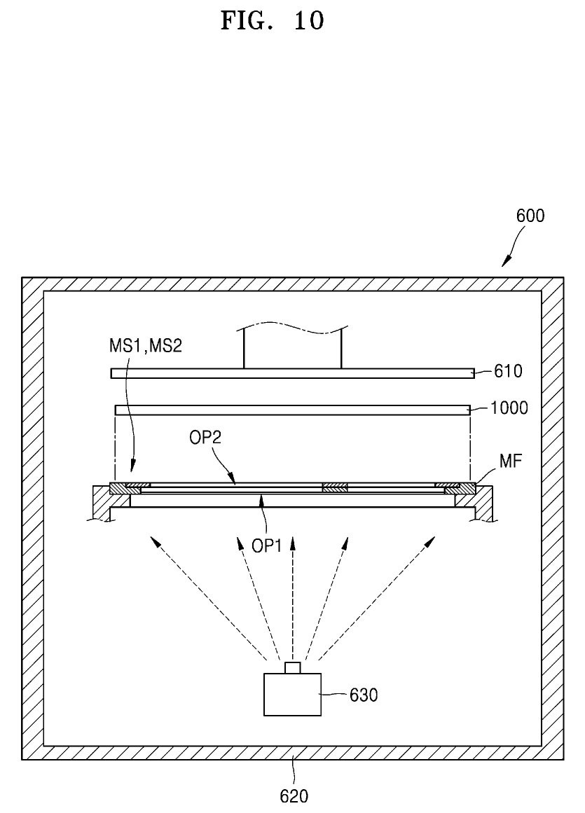

FIG. 10 is a diagram illustrating a deposition device 600 according to an embodiment of the present disclosure.

Referring to FIG. 10, the deposition device 600 includes a vacuum chamber 620 for depositing a cathode of an organic light-emitting display device or a common layer, such as a portion of an intermediate layer.

A deposition source 630 may be positioned at the bottom of the vacuum chamber 620. A mask frame assembly may be installed on the deposition source 630. Mask sticks MS1 and MS2 may be installed on the mask frame MF. The mask frame MF may have a plurality of openings corresponding to a plurality of deposition regions for simultaneously manufacturing a plurality of unit display devices. A deposition substrate 1000 may be positioned on the mask sticks MS1 and MS2. A magnet 610 that generates magnetic force so that the mask sticks MS1 and MS2 may be attached to the deposition substrate 1000 may be installed on the deposition substrate 1000.

When a deposition material is sprayed from the deposition source 630 toward the mask sticks MS1 and MS2, the deposition material that proceeds through an opening OP1 of the mask frame MF passes through an opening OP2 formed in the mask sticks MS1 and MS2 and is deposited on one surface of the deposition substrate 1000.

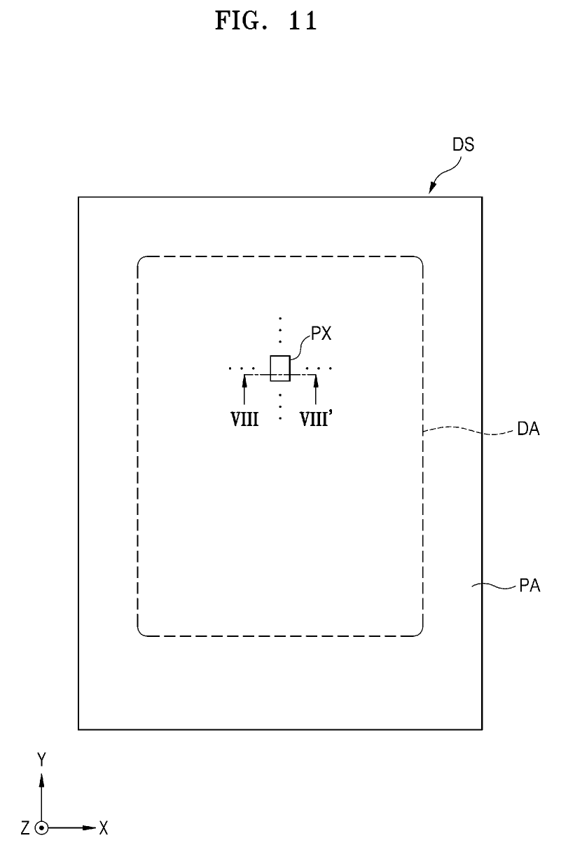

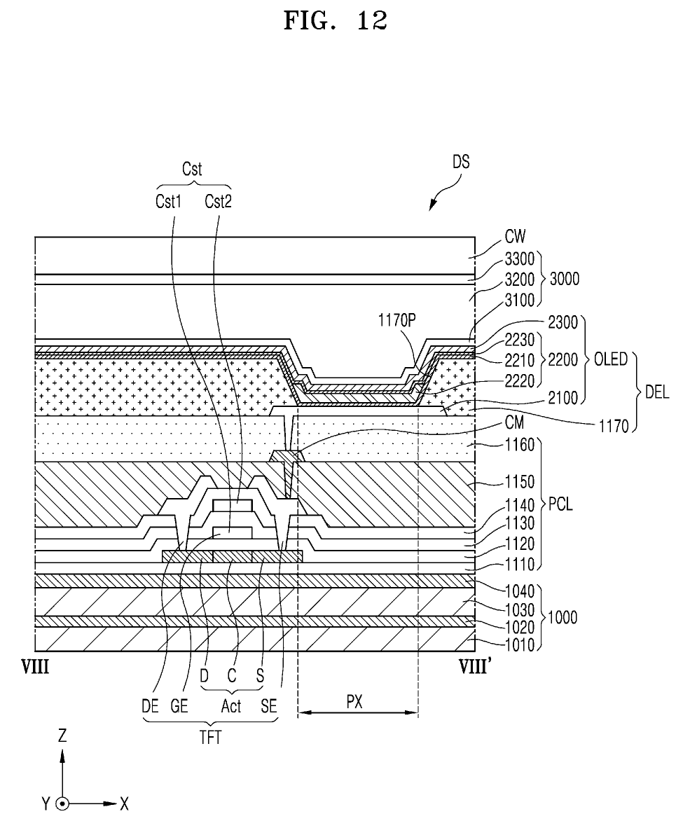

FIG. 11 is a schematic diagram illustrating an embodiment of a display device DS manufactured by the deposition device 600 illustrated in FIGS. 10, and 12 is a cross-sectional view illustrating a sub-pixel of the display device DS of FIG. 11.

Referring to FIG. 11, a display device DS manufactured according to an embodiment of the present disclosure may include a display region DA and a peripheral region PA located outside the display region DA. The display device DS may provide an image through an array of a plurality of pixels PX arranged two-dimensionally in a display region DA.

A peripheral region PA is a region in which an image is not provided and may completely or partially surround the display region DA. In the peripheral region PA, a driver, etc. for providing electrical signals or power to pixel circuits respectively corresponding to the pixels PX may be disposed. In the peripheral region PA, a pad, a region to which an electronic component or a printed circuit board may be electrically connected, may be disposed.

Hereinafter, the display device DS is described as including an organic light-emitting diode (OLED) as a light-emitting element, but the display device DS of the present disclosure is not limited thereto.

In an embodiment, the display device DS may be a light-emitting display device including an inorganic light-emitting diode, e.g., an inorganic light-emitting display device. The inorganic light-emitting diode may include a PN diode including inorganic semiconductor-based materials.

When voltage is applied to a PN junction diode in a forward direction, holes and electrons are injected, and energy generated by the recombination of the holes and electrons may be converted into light energy to emit light in a certain color. The aforementioned inorganic light-emitting diode may have a width of several to several hundred micrometers, and in some embodiments, the inorganic light-emitting diode may be referred to as a micro-LED.

In an embodiment, the display device DS may be a quantum dot light emitting display.

The display device DS may be used as a display screen for various products, such as, for example, televisions, laptops, monitors, billboards, and Internet of Things (IOT) devices, as well as portable electronic devices, such as, for example, mobile phones, smartphones, tablet personal computers (PCs), mobile communication terminals, electronic notebooks, electronic books, portable multimedia players (PMPs), navigation devices, and ultra mobile PCs (UMPCs).

In addition, the display device DS according to an embodiment may be used in wearable devices, such as, for example, smart watches, watch phones, glasses-type displays, and head mounted displays (HMDs).

In addition, the display device DS according to an embodiment may be used as, for example, a dashboard of a vehicle, a center information display (CID) placed on a center fascia or dashboard of a vehicle, a room mirror display replacing a side mirror of a vehicle, and a display screen placed on the back of a front seat as entertainment for a back seat of a vehicle.

Referring to FIG. 12, the display device DS may include a stack structure of a substrate 1000, a pixel circuit layer PCL, a display element layer DEL, and an encapsulating layer 3000.

The substrate 1000 may have a multilayer structure including a base layer including a polymer resin and an inorganic layer. For example, the substrate 1000 may include a base layer including a polymer resin and a barrier layer of an inorganic insulating layer.

For example, the substrate 1000 may include a first base layer 1010, a first barrier layer 1020, a second base layer 1030, and a second barrier layer 1040 that are sequentially stacked. The first base layer 1010 and the second base layer 1030 may include, for example, polyimide (PI), polyethersulfone (PES), polyarylate, polyetherimide (PEI), polyethylene naphthalate (PEN), polyethylene terephthalate (PET), polyphenylene sulfide (PPS), polycarbonate (PC), cellulose triacetate (TAC), and/or cellulose acetate propionate (CAP).

The first barrier layer 1020 and the second barrier layer 1040 may include an inorganic insulating material, such as, for example, silicon oxide, silicon oxynitride, and/or silicon nitride. The substrate 1000 may have flexible characteristics (e.g., the substrate 1000 may be a flexible substrate).

The pixel circuit layer PCL is arranged on the substrate 1000. FIG. 12 illustrates that the pixel circuit layer PCL includes a thin film transistor TFT and a buffer layer 1110, a first gate insulating layer 1120, a second gate insulating layer 1130, an interlayer insulating layer 1140, a first planarization insulating layer 1150, and a second planarization insulating layer 1160 disposed below and/or above components of the thin film transistor TFT. However, embodiments are not limited thereto.

The buffer layer 1110 may reduce or block the penetration of foreign substances, moisture, or external air from below the substrate 1000, and provide a flat surface on the substrate 1000.

The buffer layer 1110 may include an inorganic insulating material, such as, for example, silicon oxide, silicon oxynitride, or silicon nitride, and may be formed as a single layer or multilayer structure including the aforementioned materials.

In an embodiment, the thin film transistor TFT disposed on the buffer layer 1110 may include a semiconductor layer Act, and the semiconductor layer Act may include polysilicon.

In an embodiment, the semiconductor layer Act may include, for example, amorphous silicon, an oxide semiconductor, an organic semiconductor, etc.

The semiconductor layer Act may include a channel region C and a drain region D and a source region S respectively arranged on opposite sides of the channel region C. A gate electrode GE may overlap the channel region C.

The gate electrode GE may include a low-resistance metal material. The gate electrode GE may include a conductive material including, for example, molybdenum (Mo), aluminum (Al), copper (Cu), titanium (Ti), etc., and may be formed as a multilayer or single layer including the materials.

The first gate insulating layer 1120 disposed between the semiconductor layer Act and the gate electrode GE may include an inorganic insulating material, such as, for example, silicon oxide (SiO₂), silicon nitride (SiNX), silicon oxynitride (SiON), aluminum oxide (Al₂O₃), titanium oxide (TiO₂), tantalum oxide (Ta₂O₅), hafnium oxide (HfO₂), or zinc oxide (ZnOX). Zinc oxide (ZnOX) may include zinc oxide (ZnO) and/or zinc peroxide (ZnO₂).

The second gate insulating layer 1130 may cover the gate electrode GE. The second gate insulating layer 1130 may, similarly to the first gate insulating layer 1120, include an inorganic insulating material, such as, for example, silicon oxide (SiO₂), silicon nitride (SiNX), silicon oxynitride (SiON), aluminum oxide (Al₂O₃), titanium oxide (TiO₂), tantalum oxide (Ta₂O₅), hafnium oxide (HfO₂), or zinc oxide (ZnOX). Zinc oxide (ZnOX) may include zinc oxide (ZnO) and/or zinc peroxide (ZnO2).

An upper electrode Cst2 of a storage capacitor Cst may be disposed on the second gate insulating layer 1130. The upper electrode Cst2 may overlap the gate electrode GE below the upper electrode Cst2. The gate electrode GE and the upper electrode Cst2 overlapping with the second gate insulating layer 1130 in between may form a storage capacitor Cst. That is, the gate electrode GE may function as a lower electrode Cst1 of the storage capacitor Cst.

In this manner, the storage capacitor Cst and the thin film transistor TFT may be formed to overlap each other. In some embodiments, the storage capacitor Cst may be formed not to overlap the thin film transistor TFT.

The upper electrode Cst2 may include, for example, aluminum (Al), platinum (Pt), palladium (Pd), silver (Ag), magnesium (Mg), gold (Au), nickel (Ni), neodymium (Nd), iridium (Ir), chromium (Cr), calcium CA, molybdenum (Mo), titanium (Ti), tungsten (W), and/or copper (Cu), and may be a single layer or a plurality of layers of the aforementioned materials.

The interlayer insulating layer 1140 may cover the upper electrode Cst2. The interlayer insulating layer 1140 may include, for example, silicon oxide (SiO₂), silicon nitride (SiNX), silicon oxynitride (SiON), aluminum oxide (Aₗ₂O₃), titanium oxide (TiO₂), tantalum oxide (Ta₂O₅), hafnium oxide (HfO₂), or zinc oxide (ZnOX). Zinc oxide (ZnOX) may include zinc oxide (ZnO) and/or zinc peroxide (ZnO₂). The interlayer insulating layer 1140 may be a single layer or a plurality of layers including the aforementioned inorganic insulating material.

A drain electrode DE and a source electrode SE may each be positioned on the interlayer insulating layer 1140. The drain electrode DE and the source electrode SE may be connected to a drain region D and a source region S, respectively, through contact holes formed in insulating layers below the drain electrode DE and the source electrode SE. The drain electrode DE and source electrode SE may include a material having good conductivity. The drain electrode DE and the source electrode SE may include a conductive material including, for example, molybdenum (Mo), aluminum (Al), copper (Cu), titanium (Ti), etc., and may be formed as a multilayer or single layer including the above materials. As an example, the drain electrode DE and the source electrode SE may have a multilayer structure of Ti/Al/Ti.

The first planarization insulating layer 1150 may cover the drain electrode DE and the source electrode SE. The first planarization insulating layer 1150 may include an organic insulator, such as, for example, a general-purpose polymer, such as polymethylmethacrylate (PMMA) or polystyrene (PS), a polymer derivative having a phenol group, an acrylic polymer, an imide polymer, an aryl ether polymer, an amide polymer, a fluorinated polymer, a p-xylene polymer, a vinyl alcohol polymer, and a blend thereof.

The second planarization insulating layer 1160 may be disposed on the first planarization insulating layer 1150. The second planarization insulating layer 1160 may include the same material as that of the first planarization insulating layer 1150 and may include an organic insulator, such as, for example, a general-purpose polymer, such as PMMA or PS, a polymer derivative having a phenol group, an acrylic polymer, an imide polymer, an aryl ether polymer, an amide polymer, a fluorinated polymer, a p-xylene polymer, a vinyl alcohol polymer, and a blend thereof.

The display element layer DEL may be arranged on the pixel circuit layer PCL of the aforementioned structure. The display element layer DEL may include an OLED as a display element (e.g., a light-emitting element), and the OLED may include a stack structure of a pixel electrode 2100, an intermediate layer 2200, and a common electrode 2300. The OLED may emit, for example, red, green, or blue light, or may emit red, green, blue, or white light. The OLED may emit light through a light-emitting region, and the light-emitting region may be defined as a pixel PX.

The pixel electrode 2100 of the OLED may be electrically connected to the thin film transistor TFT through contact holes formed in the second planarization insulating layer 1160 and the first planarization insulating layer 1150 and a contact metal CM disposed on the first planarization insulating layer 1150.

The pixel electrode 2100 may include a conductive oxide, such as, for example, indium tin oxide (ITO), indium zinc oxide (IZO), zinc oxide (ZnO), indium oxide (In₂O₃), indium gallium oxide (IGO), or aluminum zinc oxide (AZO). In an embodiment, the pixel electrode 2100 may include, for example, a reflective film including silver (Ag), magnesium (Mg), aluminum (Al), platinum (Pt), palladium (Pd), gold (Au), nickel (Ni), neodymium (Nd), iridium (Ir), chromium (Cr), or compounds thereof. In an embodiment, the pixel electrode 2100 may further include a film formed of ITO, IZO, ZnO or In₂O₃ above/below the aforementioned reflective film.

A pixel defining film 1170 having an opening 1170P exposing a central portion of the pixel electrode 2100 is arranged on the pixel electrode 2100. The pixel defining film 1170 may include an organic insulating material and/or an inorganic insulating material. The opening 1170P may define the light-emitting region of light emitted from the OLED. For example, the size/width of the opening 1170P may correspond to the size/width of the light-emitting region. Accordingly, the size and/or width of the pixel PX may depend on the size and/or width of the opening 1170P of the corresponding pixel defining film 1170.

The intermediate layer 2200 may include a light-emitting layer 2220 formed to correspond to the pixel electrode 2100. In an embodiment, the light-emitting layer 2220 may include a polymer or low-molecular organic material that emits light in a certain color. In an embodiment, the light-emitting layer 2220 may include an inorganic light-emitting material or may include quantum dots.

In an embodiment, the intermediate layer 2200 may include a first functional layer 2210 and a second functional layer 2230 respectively positioned below and above the light-emitting layer 2220. The first functional layer 2210 may include, for example, a hole transport layer HTL or a hole transport layer and a hole injection layer HIL. The second functional layer 2230 is a component positioned on the light-emitting layer 2220 and may include an electron transport layer ETL and/or an electron injection layer EIL. The first functional layer 2210 and/or the second functional layer 2230 may be common layers formed to cover the entire substrate 1000, similar to the common electrode 2300 described below.

The common electrode 2300 may be disposed on the pixel electrode 2100 and may overlap the pixel electrode 2100. The common electrode 2300 may include a conductive material with a low work function. For example, in an embodiment, the common electrode 2300 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium CA, or alloys thereof. In an embodiment, the common electrode 2300 may further include a layer, such as ITO, IZO, ZnO or In₂O₃, disposed on the (semi)transparent layer including the aforementioned material. The common electrode 2300 may be formed integrally to cover the entire substrate 1000.

The encapsulating layer 3000 is arranged on the display element layer DEL and may cover the display element layer DEL. The encapsulating layer 3000 may include at least one inorganic encapsulating layer and at least one organic encapsulating layer, and as an example, FIG. 12 illustrates that the encapsulating layer 3000 includes a first inorganic encapsulating layer 3100, an organic encapsulating layer 3200, and a second inorganic encapsulating layer 3300 that are sequentially stacked.

The first inorganic encapsulating layer 3100 and the second inorganic encapsulating layer 3300 may include one or more inorganic materials including, for example, aluminum oxide, titanium oxide, tantalum oxide, hafnium oxide, zinc oxide, silicon oxide, silicon nitride, and silicon oxynitride. The organic encapsulating layer 3200 may include a polymer-based material. Polymer-based materials may include, for example, acrylic resins, epoxy resins, polyimides, and polyethylene. In an embodiment, the organic encapsulating layer 3200 may include acrylate. The organic encapsulating layer 3200 may be formed by curing a monomer or applying a polymer. The organic encapsulating layer 3200 may have transparency.

In an embodiment, a touch sensor layer may be arranged on the encapsulating layer 3000, and an optical functional layer may be arranged on the touch sensor layer. The touch sensor layer may obtain coordinate information based on external input, such as a touch event. The optical functional layer may reduce the reflectivity of light (external light) incident from outside of the device toward the display device and/or improve color purity of light emitted from the display device. In an embodiment, the optical functional layer may include a phase retarder and/or a polarizer. The phase retarder may include film type or liquid crystal coating type, and may include a λ/2 phase retarder and/or a λ/4 phase retarder. Polarizers may also include film type or liquid crystal coating type. The film type may include a stretchable synthetic resin film, and the liquid crystal coating type may include liquid crystals arranged in a certain array. The phase retarder and polarizer may further include a protective film.

An adhesive member may be disposed between the touch sensor layer and the optical functional layer. The adhesive member may be, for example, a pressure sensitive adhesive (PSA), but is not limited thereto.

A cover window CW may be disposed on the encapsulating layer 3000, and when a touch sensor layer and/or an optical functional layer are disposed, the cover window CW may be disposed on top thereof. The cover window CW may include at least one of, for example, glass, sapphire, and plastic. The cover window CW may include, for example, ultra-thin tempered glass or colorless polyimide. In an embodiment, the cover window CW may have a structure in which a flexible polymer layer is arranged on one surface of a glass substrate or may include only a polymer layer.

The cover window CW may be attached by an adhesive member. The adhesive member may be, for example, a liquid optically clear resin (OCR) or an optically clear adhesive (OCA) and/or a pressure sensitive adhesive (PSA).

The method of manufacturing a mask frame assembly and the device for manufacturing a mask frame assembly according to embodiments of the present disclosure have the effect of precisely manufacturing a mask frame assembly by combining a first mask stick and a second mask stick using a preset or calculated compensation angle.

While the present disclosure has been particularly shown and described with reference to embodiments thereof, it will be understood by those of ordinary skill in the art that various changes in form and detail may be made therein without departing from the spirit and scope of the present disclosure as defined by the following claims.

What is claimed is:

1. A method of manufacturing a mask frame assembly, the method comprising:
preparing a first mask stick arranged on one surface of a mask frame having an opening and a second mask stick crossing the first mask stick;
clamping the second mask stick at a first position, using a clamp, such that the first mask stick and the second mask stick cross at a compensation angle;
fixing the first mask stick and the second mask stick, which form the compensation angle, to each other;
moving the clamp to a second position; and
fixing the second mask stick to one side of the mask frame.

2. The method of claim 1, wherein
the first position and the second position are spaced apart in a direction in which the first mask stick extends.

3. The method of claim 1, wherein
the compensation angle is less than about 90 degrees.

4. The method of claim 2, wherein
the moving of the clamp to the second position is performed after the fixing of the first mask stick and the second mask stick to each other.

5. The method of claim 4, wherein
the fixing of the second mask stick to one side of the mask frame is performed after the moving of the clamp to the second position.

6. The method of claim 4, wherein
the first position is spaced apart from a second axis that is perpendicular to a first axis along which the first mask stick extends and passes through a crossing point of the first mask stick and the second mask stick.

7. The method of claim 6, wherein
a vertical distance between the first position and the second axis is greater than a vertical distance between the second position and the second axis.

8. The method of claim 1, wherein,
in the moving of the clamp to the second position, the clamp rotates the second mask stick in a preset direction.

9. The method of claim 8, wherein
in the moving of the clamp to the second position, the second mask stick is rotated with respect to a crossing point of the first mask stick and the second mask stick.

10. The method of claim 1, wherein
a length of the first mask stick is greater than a length of the second mask stick.

11. A device for manufacturing a mask frame assembly including a mask frame having an opening, a first mask stick arranged on the mask frame, and a second mask stick arranged to cross the first mask stick, the device comprising:
a clamp configured to clamp an end of the second mask stick and to be movable from a first position to a second position;
a fixing device configured to fix the first mask stick and the second mask stick to each other; and
a controller configured to control a position of the clamp.

12. The device of claim 11, wherein
the first position and the second position are spaced apart in a direction in which the first mask stick extends.

13. The device of claim 11, wherein
the controller is configured to dispose the clamp at the first position such that the first mask stick and the second mask stick cross at a compensation angle less than about 90 degrees.

14. The device of claim 12, wherein
the controller is configured to move the clamp to the second position after the fixing device fixes the first mask stick and the second mask stick to each other.

15. The device of claim 14, wherein
the fixing device is configured to fix the second mask stick to one side of the mask frame when the clamp is placed at the second position.

16. The device of claim 14, wherein
the first position is spaced apart from a second axis that is perpendicular to a first axis along which the first mask stick extends and passes through a crossing point of the first mask stick and the second mask stick.

17. The device of claim 16, wherein
a vertical distance between the first position and the second axis is greater than a vertical distance between the second position and the second axis.

18. The device of claim 11, wherein
the controller is configured to move the clamp from the first position to the second position to rotate the second mask stick in a preset direction.

19. The device of claim 18, wherein
the controller is configured to move the clamp from the first position to the second position to rotate the second mask stick with respect to a crossing point of the first mask stick and the second mask stick.

20. The device of claim 11, wherein
a length of the first mask stick is greater than a length of the second mask stick.
